(19) United States
(12) Patent Application Publication
(10) Pub. No.: US 2009/0224270 A1
(43) Pub. Date: Sep. 10, 2009

(54) GROUP III NITRIDE SEMICONDUCTOR THIN FILM AND GROUP III SEMICONDUCTOR LIGHT EMITTING DEVICE

(75) Inventors: Rak Jun CHOI, Suwon (KR); Naoi YOSHIKI, Tokushima (JP); Sakai SHIRO, Tokushima (JP)

Correspondence Address: MCDERMOTT WILL & EMERY LLP, 600 13TH STREET, N.W., WASHINGTON, DC, 20005-3096, US

(73) Assignees: SAMSUNG ELECTRO-MECHANICS CO., LTD., Gyunggi-do (KR); THE UNIVERSITY OF TOKUSHIMA, Tokushima (JP)

(21) Appl. No.: 12/423,283

(22) Filed: Apr. 14, 2009

Related U.S. Application Data
(62) Division of application No. 11/725,547, filed on Mar. 20, 2007.

(30) Foreign Application Priority Data
Mar. 20, 2006 (JP) 2006-0077492

(51) Int. Cl. H01L 33/00; H01L 29/205

(52) U.S. Cl. 257/94; 257/190; 257/E33.023; 257/E29.091

(57) ABSTRACT

A group III nitride semiconductor thin film and a group III nitride semiconductor light emitting device using the same. The group III nitride semiconductor thin film includes a substrate with a concave and convex portions formed thereon; a buffer layer formed on the substrate and made of a group III nitride; and an epitaxial growth layer formed on the buffer layer and made of (11-20) plane gallium nitride. The group III nitride light emitting device includes the group III nitride semiconductor thin film. The present invention allows a high quality a-plane group III nitride semiconductor thin film and a group III nitride semiconductor light emitting device using the same.

### CLAIM OF PRIORITY

This application claims the benefit of Japanese Patent Application No. 2006-0077492 filed on Mar. 20, 2006, in the Korean Intellectual Property Office, the disclosure of which is incorporated herein by reference.

### BACKGROUND OF THE INVENTION

1. Field of the Invention

The present invention relates to a group III nitride semiconductor thin film and a group III nitride semiconductor light emitting device and, more particularly, to a thin film which can be a pre-deposition layer for epitaxially growing an a-plane GaN layer.

2. Description of the Related Art

In general, the energy gap of a group III nitride semiconductor, especially a gallium nitride compound can be controlled in a broad range by adjusting the composition ratio. For example, AlₓIn_{y}Ga_{1-x-y}N (where, 0≦x≦1, 0≦y≦1 and x=y=0) is used as a direct transition type semiconductor, and its energy gap ranges from 0.7˜0.8 eV to 6 eV. This means that using a GaN-based compound as an active layer allows a light emitting device having emission colors in the entire visible ray region including red to ultraviolet region.

In order to apply a gallium nitride-based compound to such a light emitting device, a film that has high quality and high light emission efficiency in terms of the design or lifetime of the application is required. A gallium nitride-based compound has a hexagonal Wurtzite structure, and its lattice constant is very small compared to other major semiconductors (group III-V compound semiconductors or group II-VI semiconductors, etc.). This extremely small lattice constant hinders matching with a crystal of a substrate.

In general, dislocation occurs in the crystal for epitaxial growth due to the lattice mismatch or distortion (compressive distortion or tension distortion) with the crystal of the substrate. Such dislocation tends to result in dislocation defects, which degrade the quality of the epitaxial growth film. Therefore, selection of a substrate is an important factor in growing a gallium nitride compound.

In general, a sapphire substrate (c-plane) is mainly used for growing a GaN-based compound. However, even the sapphire substrate has lattice mismatch of about 15% with GaN, and thus in actuality, a buffer layer is generally adopted between the sapphire substrate and a growth layer in order to alleviate the lattice mismatch. Therefore, such a buffer layer determines the quality of the growth layer, and various types of buffer layers have been suggested recently (refer to Japanese Laid-Open Publication Application Nos. 10-242586 and 9-227298).

However, even with a buffer layer, if a c-plane of sapphire, etc. is used as a crystal base, the GaN-based compound (hereinafter, referred to as a “GaN-based growth film”), which is the growth layer, grows in c-axis direction, and thus exhibits significant c-axis characteristics in a thickness direction thereof. The GaN-based compound has strong pyroelectric properties in the c-axis direction and the interfacial stress with another GaN-based compound of a different lattice constant generates a so-called piezoelectric field. In an ideal energy band of an active layer without any stress present, the wave functions of electrons and holes exist almost symmetrically. However, when the compressive distortion or tension distortion is at work due to the difference in the lattice constants, the distance between the wave functions of the electrons and holes becomes larger due to the presence of the piezoelectric field. This translates to degradation in recombination efficiency of the active layer of the GaN-based compound grown in the c-axis direction of the substrate. In the meantime, in a case where the distance between the wave functions is decreased by the effect of the piezoelectric field, the light emission wavelength becomes longer and is variable in accordance with voltage application.

In order to remedy such problems, U.S. Patent Application Publication 2003/0198837 suggests a method of growing non-polar a-plane gallium nitride, which is not subject to the piezoelectric field.

However, the non-polar a-plane gallium nitride is not easy to be grown into a high-quality film due to its planar anisotropy. Specifically, a Ga plane (0001) grows faster than a N-plane (000-1) in the growth process of gallium nitride, and this asymmetrical growth causes dislocation defects on the film.

### SUMMARY OF THE INVENTION

The present invention has been made to solve the foregoing problems of the prior art and therefore an aspect of the present invention is to provide a higher quality GaN-based growth layer using non-polar a-plane gallium nitride.

According to an aspect of the invention, the invention provides a group III nitride semiconductor thin film which includes: a substrate with a plurality of concave and convex portions formed thereon; a buffer layer formed on the substrate and made of a group III nitride; and an epitaxial growth layer formed on the buffer layer and made of (11-20) plane gallium nitride.

According to another aspect of the invention, the invention provides a group III nitride semiconductor thin film which includes a substrate with a concave and convex portions formed thereon; a buffer layer formed on the substrate and made of a group III nitride; a middle layer formed on the buffer layer, the middle layer comprising a first layer made of a metal and a second layer made of nitrogen, the first and second layers repeatedly stacked for at least two times; and an epitaxial growth layer formed on the middle layer and made of (11-20) plane gallium nitride.

According to further another aspect of the invention, the invention provides a group III nitride semiconductor light emitting device which includes one of the above group III nitride semiconductor thin films.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a side view illustrating a group III nitride semiconductor film according to Embodiment 1;

FIG. 2 is a flowchart showing a process of forming the group III nitride semiconductor film according to Embodiment 1;

FIG. 3 is a timing chart illustrating the Pulsed Atomic Layer Epitaxy (PALE) method for growing Al/In/Ga/N laminates;

FIG. 4 is a Scanning Electron Microscope (SEM) image showing an example of displacement defect formed on an a-plane GaN film;

FIG. 5 is an SEM image showing a surface of the group III nitride semiconductor film according to Embodiment 1;

FIG. 6a is a graph showing the XRD mapping of Sample A of the group III nitride semiconductor film according to Embodiment 1;

FIG. 6b is a graph showing the XRD mapping of Sample B of the group III nitride semiconductor film according to Embodiment 1;

FIG. 7 is a schematic sectional view illustrating a group III nitride semiconductor light emitting device according to Embodiment 2; and

FIG. 8 is a graph illustrating a light emission spectrum of the group III nitride semiconductor light emitting device according to Embodiment 2.

### DETAILED DESCRIPTION OF THE PREFERRED EMBODIMENT

The following description will present exemplary embodiments of a group III nitride semiconductor film and a group III nitride semiconductor light emitting device according to the present invention with reference to the accompanying drawings.

The drawings are illustrative and the relations or ratios between thicknesses and widths of the components may somewhat differ from the actual figures of the invention. In addition, the same components may be shown in different dimensions or proportions.

### Embodiment 1

First, a group III nitride semiconductor thin film and a fabrication method thereof will be explained. The group III nitride semiconductor thin film according to Embodiment 1 includes a sapphire substrate having a substrate surface of (1-102) plane (i.e. r-plane), a low-temperature buffer layer formed on the substrate surface, a middle layer formed on the low-temperature buffer layer and a group III nitride growth layer formed on the middle layer. The r-plane sapphire substrate has a plurality of grooves formed in a stripe pattern on the r-plane sapphire substrate. Here, “−1” of (1-102) indicates “1” with a bar at the top. The miller indices will be represented in the same fashion throughout the specification. In addition, Embodiment 1 exemplifies a (11-20) plane (i.e. a-plane) GaN layer as an example of a group III nitride growth layer.

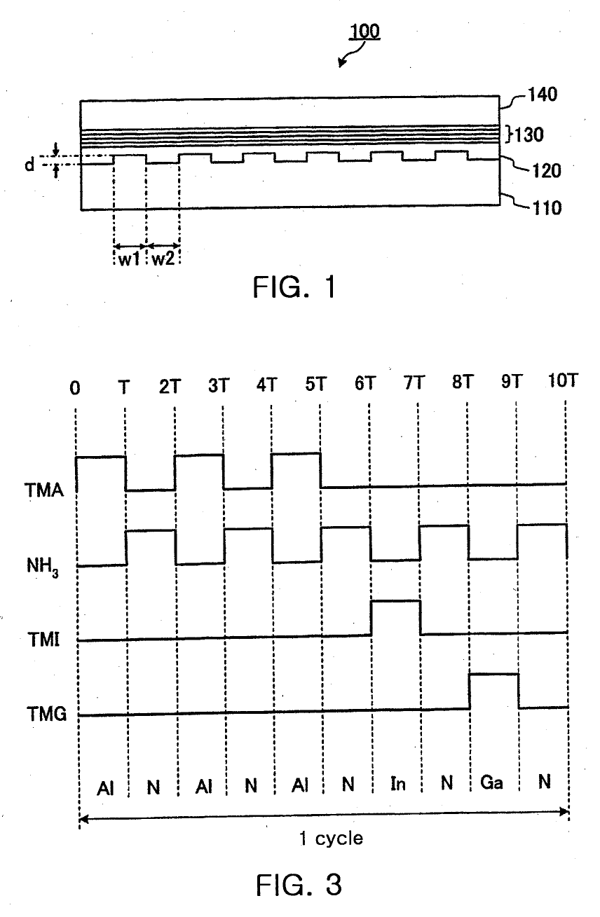

FIG. 1 is a schematic sectional view illustrating a group III nitride semiconductor thin film according to Embodiment 1.

Referring to FIG. 1, the group III nitride semiconductor thin film 100 includes a sapphire substrate 110 with an r-plane as a substrate surface, a buffer layer 120 formed on the sapphire substrate 110, a middle layer 130 formed on the buffer layer 120 and an undoped a-plane GaN layer 140 formed on the middle layer 130.

On a surface of the sapphire substrate 110, a plurality of arc-shaped grooves defined by a ridge width w1, a groove width w2 and a groove depth d are formed. The buffer layer 120 is installed for the purpose of lattice matching between the r-plane sapphire substrate and a layer formed on the buffer layer 120, and can be composed of GaN, AlN and AlInN. In this embodiment, the buffer layer 120 is made of AlInN. The middle layer 130 is composed of a stack of laminates of the same composition, and functions to further alleviate the lattice mismatch between the buffer layer 120 and the a-plane GaN layer 140. Each of the laminates constituting the middle layer 130 is formed by sequentially stacking several different materials. For example, each laminate can be a Ga/N/GaN laminate with Ga, N and GaN sequentially layered, or an Al/In/Ga/N laminate with Al, In, Ga and N sequentially layered.

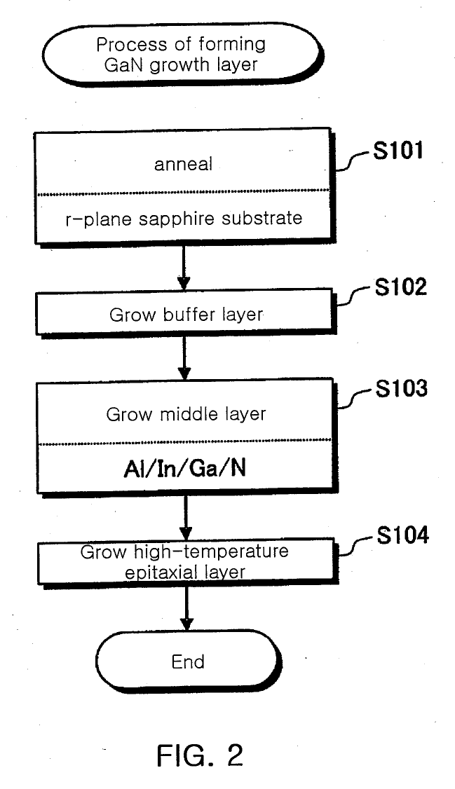

Now, a method of manufacturing the group III nitride semiconductor thin film 100 will be explained. In particular, it is preferable to use the sapphire substrate 110 with the stripe pattern and the Al/In/Ga/N laminates repeatedly stacked in tens of layers as the middle layer 130. FIG. 2 is a flowchart showing a fabrication method, i.e., a process of forming the GaN thin film.

First, a single-crystal r-plane sapphire substrate 110 was prepared and a plurality of grooves in a stripe pattern defined by a ridge width w1, a groove width w2 and a groove depth d were formed along the (0001) plane by a general photolithography process and Reactive Ion Etching (RIE). Hereinafter, the sapphire substrate 110 with the stripe pattern formed thereon is referred to as a “patterned sapphire substrate” 110.

Then, the patterned sapphire substrate 110 was cleaned using a suitable solution and inserted in a reactive chamber of a Metal Organic Chemical Vapor Deposition (MOCVD) apparatus. In the entire process in the reactive chamber, the temperature of the substrate was regulated at 1150° C., and the substrate was annealed for about 10 minutes in a hydrogen atmosphere, S101.

Next, in order to grow a buffer layer 120 of AlInN on the patterned sapphire substrate 110, hydrogen and nitrogen were fed into the reactive chamber as carrier gases in the flow rates of 18 SLM and 15 SLM, respectively, and ammonia (NH₃), trimethylaluminum (TMA) and trimethylindium (TMI) were fed in the flow rates of 1 SLM, 43 SCCM and 300 SCCM as source gases. At this time, the temperature of the substrate was regulated at 850° C., and the growth time was set for 4 minutes. Thereby, an AlInN buffer layer having a thickness of 5 to 10 nm was obtained, S102. In particular, the AlInN buffer layer 120 was grown at the atmospheric pressure.

Subsequently, the temperature was set at 850 to 1100° C., and Al/In/Ga/N laminates were grown repeatedly for preset number of times to form the middle layer 130, S103. The Al/In/Ga/N laminates are formed by Pulsed Atomic Layer Epitaxy (PALE). This entails sequentially adopting a plurality of different materials according to predetermined pulse signals into the reactive chamber of the MOCVD apparatus. To form the Al/In/Ga/N laminate, trimethylaluminum (TMA), trimethylindum (TMI), trimethylgallium (TMG) and ammonia (NH₃) are used.

FIG. 3 is a timing chart of the PALE method for growing the Al/In/Ga/N laminates. Referring to FIG. 3, 1 cycle consists of 10 clocks (time: 0 to 10T). Specifically, only TMA was fed at a first clock (0-T) and only NH₃ was fed at a second clock (T-2T). In the same fashion, at a third clock (2T-3T), a fourth clock (3T-4T), a fifth clock (4T-5T) and a sixth clock (5T-6T), TMA, NH₃, TMA and NH₃ were fed sequentially. Then, only TMI was fed at a seventh clock (6T-7T), only NH₃ was fed at an eighth clock (7T-8T), only TMG was fed at a ninth clock (8T-9T), and only NH₃ was fed at a tenth clock (9T-10T). Here, it should be noted that NH₃ was fed after TMA, TMI and TMG, which are organic metals. This kind of control in feeding the source gases allows sequentially growing Al, N, Al, N, Al, N, In, N, Ga and N on the low-temperature pulse layer 120. That is, the above described 1 cycle forms an AlN/InN/GaN laminate and a combined layer on the buffer layer 120.

The middle layer 130 of Al/In/Ga/N laminates was formed by repeatedly implementing the procedure for forming an Al/In/Ga/N laminate by the above-described 1 cycle for multiple times. Preferably, the Al/In/Ga/N laminates are formed by 2 to 100 cycles, and more preferably, by 10 to 20 cycles. Preferably, 1 clock T consists of 1 to 60 seconds, and more preferably, 2 to 10 seconds. In the meantime, it is preferable that the temperature of the substrate is regulated in a range of 850° C. to 1100° C.

In addition, in order to grow a high-temperature epitaxial layer, i.e., an undoped a-plane GaN layer 140 on the middle layer 130, hydrogen and nitrogen were fed in the flow rates of 11.6 SLM and 14 SLM, respectively, as carrier gases into the reactive chamber, and ammonia (NH₃) and trimethylgallium (TMG) were fed in the flow rates of 5.0 SLM and 42 SCCM (203 μmol/min), respectively, as source gases. At this time, the temperature of the substrate was regulated at 1100° C., and the growth time was set for 80 minutes. Thereby, an a-plane GaN layer 140 with a thickness of about 13 μm was obtained, S104. This a-plane GaN layer 140 was also grown at the atmospheric pressure.

Through the above described method, two a-plane GaN thin film samples with the difference only in the stripe pattern of the sapphire substrate 110 were obtained. One of the samples (hereinafter, “sample A”) with the arc-shaped pattern had a ridge width w1 of 5 μm, a groove width w2 of 5 μm and a groove depth d of 0.53 μm. The other one (hereinafter, “sample B”) of the samples with the stripe pattern had a ridge width w1 of 700 μm, a groove width w2 of 500 μm and a groove depth d of 0.30 μm.

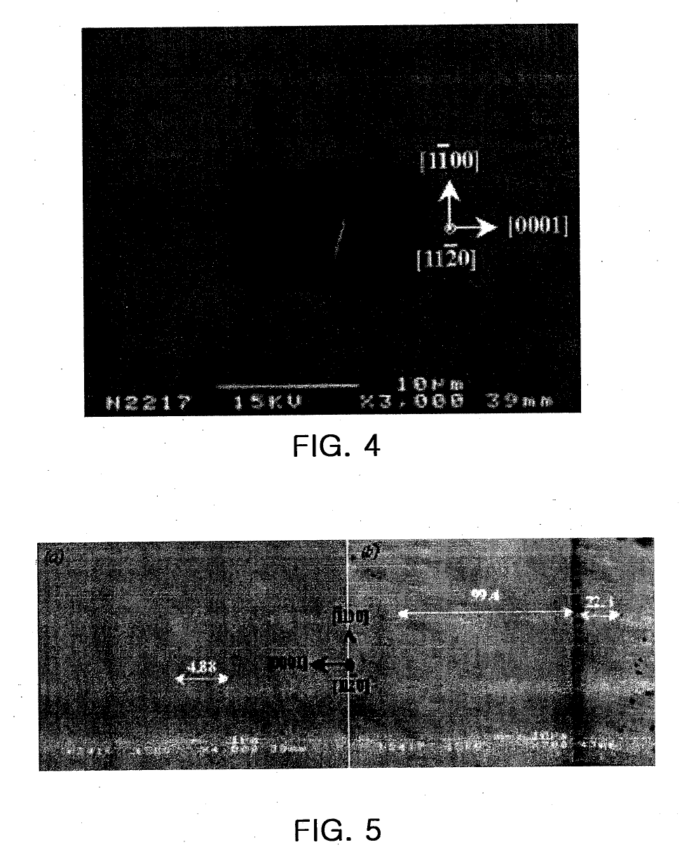

FIG. 4 is an SEM image of dislocation defects formed on the a-plane GaN layer obtained by a conventional method. As shown in FIG. 4, the dislocation defects are typically characterized by a triangular morphology. FIG. 5 presents SEM surface images of sample A and sample B of the a-plane GaN layers, presented side by side for comparison.

Referring to the SEM image (a) of FIG. 5, the smooth region and the rough region can be clearly distinguished. On the other hand, in the SEM image of sample B, no dislocation defects can be found in the length of 100 μm (hereinafter, referred to as a “pit-free region”). The pit-free region indicates that the sample B has a smooth-surface morphology growing along the direction (0001). While growing a GaN crystal, dislocation defects are formed on the N-plane grown along (000-1), which increases the concave and convex portions of the surface. This is due to the fact that (0001) plane grows faster than (000-1) plane by the basic difference between (0001) plane, which is the Ga plane and the (000-1) plane, which is the N-plane. Consequently, this asymmetrical growth causes dislocation defects. In particular, as shown in the SEM image (b) of the sample B, the Ga plane forms (1-101) plane in an arrowhead shape, while the N-plane forms a linear section. In other words, a decrease in dislocation is observed in the left side of the roughened area.

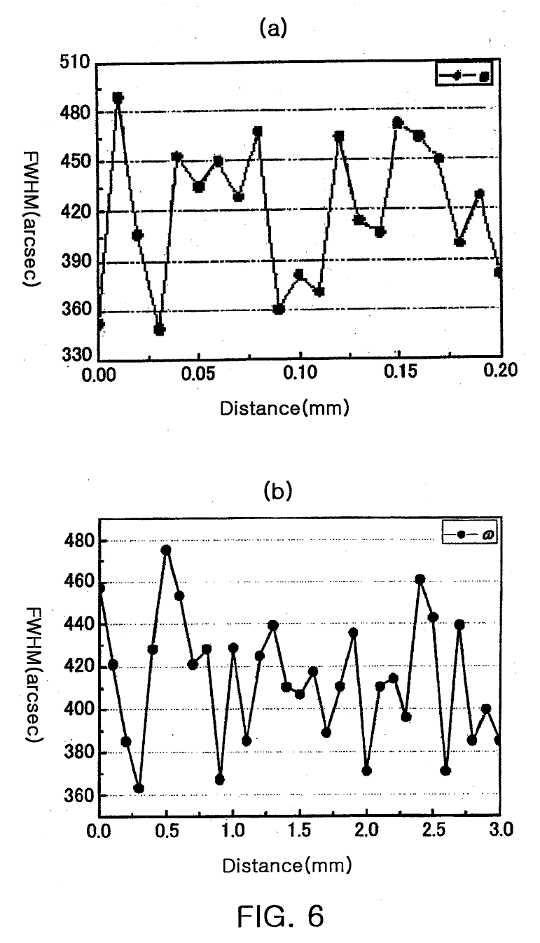

FIGS. 6a and 6b are XRD mappings obtained from XRD diffraction spectrums in the samples A and B, respectively. These graphs are obtained by aligning an X-ray irradiator of 2 μm×5 mm in parallel with the stripe pattern (with the 2 μm side of an X-ray beam aligned with the short side of the stripe pattern), and irradiating in a perpendicular direction to the stripe pattern. As shown in FIG. 6a, the sample A exhibits a Full Width at Half Maximum (FWHM) between 353 arcsec and 490 arcsec. As shown in FIG. 6b, the sample B exhibits a FWHM between 363 arcsec and 475 arcsec.

According to the results, the a-plane GaN layer formed on the r-plane sapphire substrate with the stripe pattern did not exhibit the dislocation defects observed in the prior art and had almost a uniform surface.

As described above, according to Embodiment 1, a high quality a-plane GaN layer can be grown by using the r-plane sapphire substrate 110 with the stripe pattern and sequentially forming the buffer layer 120 and the middle layer 130 of Al/In/Ga/N.

In the meantime, although Embodiment 1 exemplifies adopting GaN for the high-temperature epitaxial layer, other GaN-based compounds such as AlGaN instead of GaN can also be grown to allow an equally excellent-quality thin film. Further, the substrate is not limited to the r-plane sapphire substrate and can also be made of MgO, LiGaO₃, LiAlO₃, SiC, Si, etc. to form the above-described stripe pattern, which results in an equally excellent-quality a-plane GaN thin film.

Further, the concave and convex portions of the substrate can be formed in 1-100 direction of GaN, in a direction inclined by 30° or 60° about this direction and in a perpendicular direction to this direction, each of the convex portions can have a width in the range of 0.001 to 1 mm, and each of the concave portions has depth in the range of 0.001 to 1 μm, in order to improve the quality of the a-plane GaN thin film. In particular, the concave and convex portions can be inclined by ±5° about (1-100) direction of GaN.

### Embodiment 2

The group III nitride semiconductor thin film according to Embodiment 1 can be utilized as a pre-deposition layer or underlayer for a group III nitride semiconductor light emitting device of an LED or a semiconductor laser. Embodiment 2 describes a case where the group III nitride semiconductor thin film according to Embodiment 1 is applied to a light emitting device.

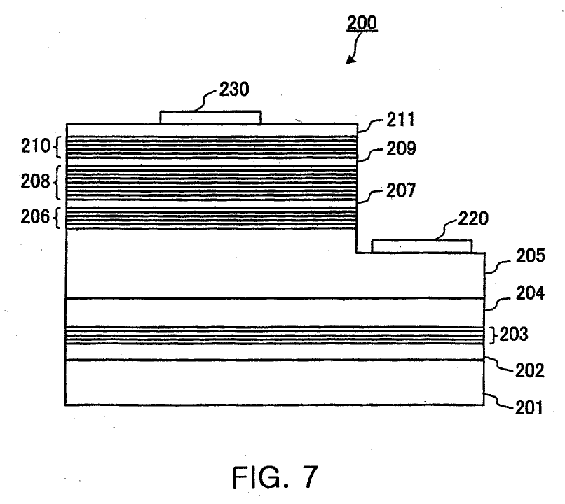

FIG. 7 is a schematic sectional view illustrating a group III nitride light emitting device according to Embodiment 2. The group III nitride semiconductor light emitting device 200 shown in FIG. 7 includes an r-plane patterned sapphire substrate 201, a buffer layer 202 of AlInN, a middle layer 203 of Al/In/Ga/N laminates, an undoped a-plane GaN layer 204, an n-contact layer 205, an n-clad layer 206, an n-middle layer 207, an active layer 208, a p-block layer 209, a p-clad layer 210, a p-contact layer 211, formed in their order.

Here, the thin film portion composed of the patterned sapphire substrate 201, the buffer layer 202, the middle layer 203 and the a-plane GaN layer 204 is identical to the group III nitride semiconductor thin film 100 according to Embodiment 1.

Now, a process of manufacturing the group III nitride semiconductor light emitting device 200 will be explained. First, the n-contact layer 205 is grown on the a-plane GaN thin film of sample B in Embodiment 1 by doping Si on GaN. Then, the n-clad layer 206 of super lattice structure is formed by doping Si on (AlGaN/GaN)ⁿ (e.g. n=50). The n-middle layer 207 was grown by doping Si on AlGaN.

The active layer 208 has a multiple quantum well structure made of (InGaN/GaN)ⁿ (e.g. n=5) and is grown by feeding Ga and In in the flow rates of 10 SCCM and 300 SCCM, respectively, as the source gases. The p-block layer 209 is grown by injecting Mg to AlGaN, and the p-clad layer 210 having a super lattice structure is formed by doping Mg on (AlGaN/GaN)ⁿ (e.g. n=50). The p-clad layer 210 is grown at 1050° C. by feeding TMG, Cp₂Mg and NH₃ in the flow rates of 20 sccm (96.7 μmol/min), 60 sccm (0.2 μmol/min) and 3.0 SLM, respectively. The p-contact layer 211 is grown by doping Mg on GaN.

A part of each of the n-contact layer 205, the n-clad layer 206, the n-middle layer 207, the active layer 208, the p-block layer 209, the p-clad layer 210 and the p-contact layer 211 is eliminated by etching to expose a part of the n-contact layer 205, and an n-electrode 220 is installed on an exposed portion of the n-contact layer 205. Also, a p-electrode 230 is formed on the p-contact layer 211. The n-electrode 220 is formed by depositing In, while the p-electrode 230 is formed by depositing Ni (100 Å)/Au (100 Å) via electron beams. Thereby, a light emitting device of 100×100 μm² is obtained.

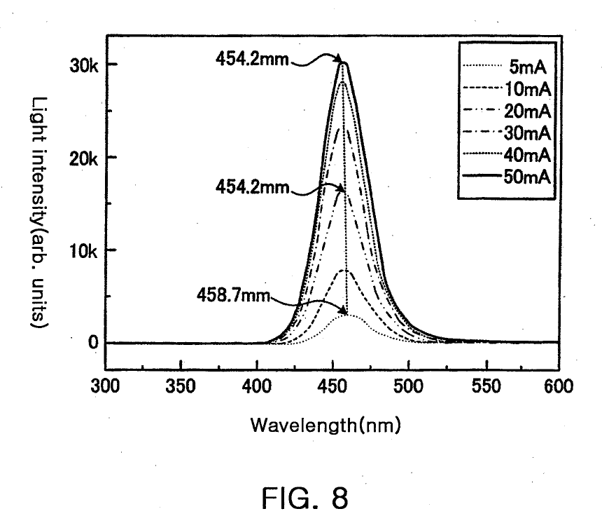

FIG. 8 is measurement results of electroluminescence of the above-obtained light emitting device. As shown in FIG. 8, the light emitting device exhibits a light emission peak of 459 nm at a driving current of 5 mA, and a light emission peak of 454 nm at a driving current of 50 mA.

As explained above, according to Embodiment 2, a high quality light emitting device is formed on the a-plane GaN thin film, thereby realizing a blue light emitting device with high reliability and sufficient light emission intensity.

In the above described Embodiments 1 and 2, the middle layer formed between the buffer layer and the a-plane GaN but the middle layer can be omitted, and the a-plane GaN layer can be formed directly on the buffer layer. This also allows the same effect of the stripe pattern of the substrate, that is, the reduction of the dislocation defects formed on the a-plane GaN layer.

In addition, the above described Embodiments 1 and 2 exemplify a stripe pattern composed of a plurality of grooves formed in the substrate but the present invention is not limited thereto, and there may be various sectional shapes of concave and convex portions such as a triangle, a rectangle, a circle, etc.

According to the present invention as set forth above, the group III nitride semiconductor thin film is useful as a pre-deposition layer or underlayer for forming a GaN-based compound, and in particular, as a component of a group III nitride semiconductor light emitting device. Accordingly, the present invention provides a high-quality a-plane group III nitride semiconductor thin film and a group III nitride semiconductor light emitting device using the same.

While the present invention has been shown and described in connection with the exemplary embodiments, it will be apparent to those skilled in the art that modifications and variations can be made without departing from the spirit and scope of the invention as defined by the appended claims.

1-9. (canceled)

10. A group III nitride semiconductor thin film comprising:
a substrate with a concave and convex portions formed thereon;
a buffer layer formed on the substrate and made of a group III nitride;
a middle layer formed on the buffer layer, the middle layer comprising a first layer made of a metal and a second layer made of nitrogen, the first and second layers repeatedly stacked for at least two times; and
an epitaxial growth layer formed on the middle layer and made of (11-20) plane gallium nitride.

11. The group III nitride semiconductor thin film according to claim 10, wherein the middle layer comprises Al/In/Ga/N.

12. The group III nitride semiconductor thin film according to claim 10, wherein the buffer layer comprises AlInN.

13. The group III nitride semiconductor thin film according to claim 10, wherein the concave and convex portions of the substrate comprise a plurality of stripe shaped ridges with a plurality of grooves.

14. The group III nitride semiconductor thin film according to claim 13, wherein each of the ridges has a width of 0.001 to 1 mm, each of the grooves has a width of 0.001 to 1 mm and a depth of 0.01 to 1 μm.

15. The group III nitride semiconductor thin film according to claim 10, wherein the concave and convex portions are formed in (1-100) direction of gallium nitride, in a direction inclined by 30° about (1-100) direction, in a direction inclined by 60° about (1-100) direction or in direction perpendicular to (1-100) direction, each of the convex portions has a width of 0.001 to 1 mm, and each of the concave portions has a depth of 0.01 to 1 μm.

16. The group III nitride semiconductor thin film according to claim 15, wherein the concave and convex portions are inclined by ±5′ about (1-100) direction of gallium nitride.

17. The group III nitride semiconductor thin film according to claim 10, wherein the substrate comprises a (1-102) plane sapphire substrate.

18. The group III nitride semiconductor thin film according to claim 10, wherein the substrate comprises a material selected from the group consisting of MgO, LiGaO₃, LiAlO₃, SiC and Si.

19. A group III nitride semiconductor light emitting device comprising the group III nitride semiconductor thin film described in claim 10.
